(19) United States
(12) Patent Application Publication
(10) Pub. No.: US 2011/0207048 A1
(43) Pub. Date: Aug. 25, 2011

(54) METHOD OF PRODUCING ELECTRICAL COMPONENT, ELECTRICAL COMPONENT PRODUCTION DEVICE, AND PHOTOSENSITIVE RESIST

(76) Inventor: Yuki ITOU, Miyagi (JP)

(21) Appl. No.: 13/027,402

(22) Filed: Feb. 15, 2011

(30) Foreign Application Priority Data
Feb. 19, 2010 (JP) 2010-035317

(51) Int. Cl. G03F 7/20; G03F 7/004; B05D 5/12; C08F 2/48; B01F 13/00

(52) U.S. Cl. 430/270.1; 430/311; 427/99.2; 427/508; 366/342

(57) ABSTRACT

A method of producing an electrical component includes the steps of: selectively forming a powder containing organic layer containing conductive powders on an exposed surface of a first conductive member exposed through an opening portion formed in an insulation film; and thermally processing the powder containing organic layer to agglutinate the conductive powders so that a second conductive member electrically connected to the first conductive member is formed on the exposed surface.

### BACKGROUND OF THE INVENTION AND RELATED ART STATEMENT

The present invention relates to a method of producing an electrical component, an electrical component production device, and a photosensitive resist.

In a conventional method of producing an electrical component, in order to form a minute bump, a minute wiring portion or a minute electrode, it is necessary to perform a large number of steps. Such steps include a film forming step for forming a metal film on a surface of a substrate; a photo lithography step for forming a pattern of a photosensitive resist coated on a surface of the metal film with an exposure developing device; an etching step for etching the metal film according to the pattern; and the likes.

In order to reduce the number of the steps, Patent Reference has disclosed a conventional method of manufacturing a solder circuit board, in which a bump is formed with solder powders. In the conventional method disclosed in Patent Reference, at first, a conductive circuit is formed on a print circuit board, and an electrode of the conductive circuit is configured to have a sticky surface. In the next step, solder powders are attached to the surface of the electrode, thereby forming the solder circuit board.
Patent Reference: Japanese Patent Publication No. 2008-41803

According to the conventional method disclosed in Patent Reference, when the solder circuit is formed with solder powders, it is desirable to use solder powders having a relatively uniform solder particle size, so that the bumps have a uniform height after being formed using solder powders. Further, when an opening portion is provided for attaching solder powders to the surface of the electrode, it is desirable to form the opening portion having a specific size in consideration of a size of solder powders, so that only one solder particle can enter the opening portion. Still further, it is desirable to treat the surface of the electrode with chemical, so that solder powders can be easily attached to the surface of the electrode.

According to Patent Reference, the conventional method is applied to the print circuit board, and may be applied to an LSI (Large Scale Integrated circuit) chip. However, solder powders have a particle size of about 70 μm, so that it is difficult to form a minute bump (less than 10 μm) required for the LSI chip.

In the conventional method disclosed in Patent Reference, when solder powders are formed to have a small particle size, it is possible to form a minute bump. However, when solder powders have such a small particle size, it is difficult to select proper solder powders due to a large influence of static electricity. In other words, solder powders may be easily attached to an area other than the surface of the electrode due to a large influence of static electricity. Accordingly, it is difficult to attach solder powders to only the surface of the electrode as a target.

Further, in order to form the bumps having a uniform height, it is necessary to use solder powders having a uniform particle size. In this case, it is difficult to form the bumps having various sizes.

In view of the problems described above, an object of the present invention is to provide a method of producing an electrical component, an electrical component production device, and a photosensitive resist capable of solving the problems of the conventional method. In the present invention, it is possible to easily form a bump, a wiring portion, and an electrode.

Further objects and advantages of the invention will be apparent from the following description of the invention.

### SUMMARY OF THE INVENTION

In order to attain the objects described above, according to a first aspect of the present invention, a method of producing an electrical component includes the steps of: selectively forming a powder containing organic layer containing conductive powders on an exposed surface of a first conductive member exposed through an opening portion formed in an insulation film; and thermally processing the powder containing organic layer to agglutinate the conductive powders so that a second conductive member electrically connected to the first conductive member is formed on the exposed surface.

As described above, in the first aspect of the present invention, the method of producing the electrical component includes the steps of: selectively forming the powder containing organic layer containing the conductive powders on the exposed surface of the first conductive member exposed through the opening portion formed in the insulation film; and thermally processing the powder containing organic layer to agglutinate the conductive powders so that the second conductive member electrically connected to the first conductive member is formed on the exposed surface.

Accordingly, in the first aspect of the present invention, it is possible to adjust a size of the second conductive member through adjusting a thickness of the powder containing organic layer coated on the exposed surface, an amount of the conductive powders contained in the powder containing organic layer, or a particle size of the conductive powders. As a result, it is possible to freely design the size of the second conductive member.

In the first aspect of the present invention, the conductive powders are contained in the powder containing organic layer. Accordingly, it is possible to select proper conductive powders regardless of a large influence of static electricity. As a result, it is possible to select the conductive powders having a minute size, thereby making it possible to form the second conductive member having a minute size.

According to a second aspect of the present invention, in the method of producing the electrical component in the first aspect of the present invention, the powder containing organic layer is formed of a photosensitive resist containing the conductive powders. Further, in the step of selectively forming the powder containing organic layer on the exposed surface of the first conductive member, the method of producing the electrical component includes the steps of uniformly coating the photosensitive resist containing the conductive powders on the insulation film and the exposed surface, and removing the photosensitive resist coated on the insulation film with an exposure developing device.

As described above, in the second aspect of the present invention, the method of producing the electrical component includes the steps of uniformly coating the photosensitive resist containing the conductive powders on the insulation film and the exposed surface, and removing the photosensitive resist coated on the insulation film with the exposure developing device. Accordingly, it is possible to selectively form the powder containing organic layer formed of the photosensitive resist containing the conductive powders on the exposed surface.

According to a third aspect of the present invention, in the method of producing the electrical component in the first aspect of the present invention, the powder containing organic layer is formed of a photosensitive resist containing the conductive powders. Further, in the step of selectively forming the powder containing organic layer on the exposed surface of the first conductive member, the method of producing the electrical component includes the steps of uniformly coating a photosensitive resist without the conductive powders on the insulation film and the exposed surface; removing the photosensitive resist coated on the exposed surface with an exposure developing device so that a hole or a groove reaching the exposed surface is formed; and filling the hole or the groove with the photosensitive resist containing the conductive powders.

As described above, in the third aspect of the present invention, the method of producing the electrical component includes the steps of uniformly coating the photosensitive resist without the conductive powders on the insulation film and the exposed surface; removing the photosensitive resist coated on the exposed surface with the exposure developing device so that the hole or the groove reaching the exposed surface is formed; and filling the hole or the groove with the photosensitive resist containing the conductive powders. Accordingly, it is possible to selectively form the powder containing organic layer formed of the photosensitive resist containing the conductive powders on the exposed surface.

According to a fourth aspect of the present invention, in the method of producing the electrical component in the first aspect of the present invention, a height of the second conductive member is adjusted through adjusting a thickness of the powder containing organic layer coated on the exposed surface, or an amount of the conductive powders contained in the powder containing organic layer.

As described above, in the fourth aspect of the present invention, it is possible to adjust a size of the second conductive member through adjusting a thickness of the powder containing organic layer coated on the exposed surface, or an amount of the conductive powders contained in the powder containing organic layer. As a result, it is possible to freely design the size of the second conductive member.

According to a fifth aspect of the present invention, in the method of producing the electrical component in the first aspect of the present invention, the second conductive member is formed of at least one of a bump, a wiring portion, or an electrode.

As described above, in the fifth aspect of the present invention, it is possible to freely design a size of the second conductive member. As a result, it is possible to freely design a size of the bump, the wiring portion, or the electrode.

According to a sixth aspect of the present invention, in the method of producing the electrical component in the first aspect of the present invention, the conductive powders are solder powders. The solder powders having a minute size are readily available, and easy to be agglutinated through a thermal process. As a result, it is possible to freely design a size of the bump, the wiring portion, or the electrode.

According to a seventh aspect of the present invention, an electrical component production device includes a powder containing organic solution production device for mixing conductive powders in an organic solvent to produce a powder containing organic solution. Accordingly, with the powder containing organic solution production device, it is possible to uniformly disperse the conductive powders in the organic solvent, and uniformly supply the powder containing organic solution. As a result, it is possible to freely design a size of the bump, the wiring portion, or the electrode.

According to an eighth aspect of the present invention, a photosensitive resist contains conductive powders capable of being agglutinated through a thermal process.

Accordingly, it is possible to provide the photosensitive resist containing the conductive powders capable of being agglutinated through the thermal process.

As described above, in the present invention, it is possible to freely design a size of the bump, the wiring portion, or the electrode.

### BRIEF DESCRIPTION OF THE DRAWINGS

FIGS. 1(A) to 1(F) are schematic sectional views showing an electrical component in a manufacturing process using a method of producing the electrical component according to a first embodiment of the present invention;

FIGS. 2(A) to 2(D) are schematic sectional views No. 1 showing an electrical component in a manufacturing process using a method of producing the electrical component according to a second embodiment of the present invention;

FIGS. 3(A) to 3(C) are schematic sectional views No. 2 showing the electrical component in the manufacturing process using the method of producing the electrical component according to the second embodiment of the present invention; and

FIG. 4 is a schematic view showing a configuration of an electrical component production device according to a third embodiment of the present invention.

### DETAILED DESCRIPTION OF PREFERRED EMBODIMENTS

Hereunder, preferred embodiments of the present invention will be explained with reference to the accompanying drawings.

### First Embodiment

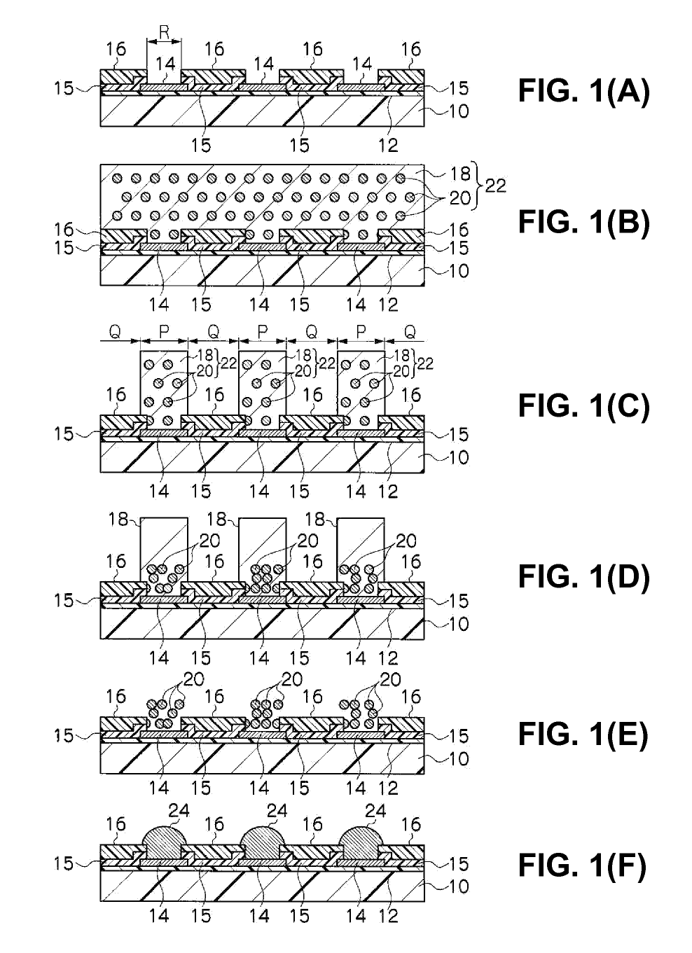

A first embodiment of the present invention will be explained with reference to FIGS. 1(A) to 1(F). FIGS. 1(A) to 1(F) are schematic sectional views showing an electrical component in a manufacturing process using a method of producing the electrical component according to the first embodiment of the present invention.

In the embodiment, a bump, a wiring portion, or an electrode is formed with the method of producing the electrical component according to the first embodiment of the present invention. In the following description, a process of forming the bump is explained as an example.

As shown in FIG. 1(A), a preparation process is performed. More specifically, an insulation film 12 is formed on a substrate 10 with a CVD (Chemical Vapor Deposition) method, and a metal film to be electrodes 14 is formed on the insulation film 12 with a vacuum deposition method. Then, the metal film is processed with a photolithography process and an etching process to form the electrodes 14.

In the next step, insulation films 15 and 16 are uniformly formed on the insulation film 12 and the electrodes 14 with the CVD method. Then, opening portions with a diameter R are formed in the insulation films 15 and 16 on the electrodes 14 with the photolithography process and the etching process. The opening portions have a shape according to a purpose thereof. For example, in the case of forming the bump, the opening portions have a circular shape. In the case of forming the wiring portion, the opening portions have a groove shape. Through the process described above, it is possible to expose upper surfaces of the electrodes 14 in a desirable shape through the opening portions formed in the insulation films 15 and 16.

In the next step, as shown in FIG. 1(B), a powder containing photosensitive resist coating process is performed. More specifically, a powder containing photosensitive resist 22 is uniformly coated on the insulation film 16 and the exposed surfaces of the electrodes 14. Accordingly, it is possible to form a uniform layer of the powder containing photosensitive resist 22.

In the embodiment, the powder containing photosensitive resist 22 is a mixture of a photosensitive resist 18 and metal powders 20 with electrical conductivity. It is preferred that the metal powders 20 are easily agglutinated through a thermal process. A type of metal is selected according to an application. For example, the metal powders 20 may include solder powders as metal powders to be easily agglutinated.

In the embodiment, the powder containing photosensitive resist 22 is coated to have a thickness according to a height of the bump to be formed. Further, an amount of the metal powders 20 contained in the photosensitive resist 18 is determined according to a desired height of the bump.

In the next step, as shown in FIG. 1(C), an exposure developing process is performed. More specifically, the powder containing photosensitive resist 22 coated on the insulation film 16 is removed within a range of a width Q with an exposure developing device, so that the powder containing photosensitive resist 22 coated on the exposed surfaces of the electrodes 14 remains within a range of a width P.

Through the step described above, it is possible to selectively form layers of the powder containing photosensitive resist 22 only on the exposed surfaces of the electrodes 14, where the bumps are to be formed. It is noted that the exposure developing device includes a well-known device, and detailed explanation is omitted.

In the next step, as shown in FIG. 1(D), a thermal process is performed. More specifically, the powder containing photosensitive resist 22 is heated with a heating device (at a temperature of, for example, about 200° C.), so that the metal powders 20 in the powder containing photosensitive resist 22 are agglutinated. Accordingly, the metal powders 20 thus agglutinated start sinking in the powder containing photosensitive resist 22.

In the next step, as shown in FIG. 1(E), a photosensitive resist removal process is performed. More specifically, the powder containing photosensitive resist 22 is exposed in an oxygen environment or an ozone environment, or UV (Ultra Violet) light is irradiated on the powder containing photosensitive resist 22, thereby removing the photosensitive resist 18. Accordingly, it is possible to leave only the metal powders 20 on the exposed surfaces of the electrodes 14.

In the next step, as shown in FIG. 1(F), the thermal process is performed one more time. More specifically, the metal powders 20 thus agglutinated are heated with a heating device (at a temperature of, for example, about 250° C. to 350° C.), so that the metal powders 20 are melted together to form bumps 24. Further, in this step, the metal powders 20 are electrically connected to the electrodes 14. When the metal powders 20 are easily agglutinated, this step may not be necessary.

As described above, with the method of producing the electrical component, the metal powders 20 contained in the photosensitive resist 18 are coated on the exposed surfaces of the electrodes 14, and the metal powders 20 are agglutinated. Accordingly, it is possible to form the bump with great flexibility. More specifically, when the powder containing photosensitive resist 22 thus coated has a large thickness, it is possible to increase a height of the bumps 24. Further, when the amount of the metal powders 20 in the powder containing photosensitive resist 22 increases, it is possible to increase a height of the bumps 24.

Further, in the embodiment, the metal powders 20 have a minute size and are mixed in the photosensitive resist 18. Accordingly, it is possible to minimize an influence of static electricity thereon. In the above description, the method of producing the electrical component is adopted to form the bumps 24, and may be applied to form a wiring portion or an electrode with great flexibility through a similar process.

### Second Embodiment

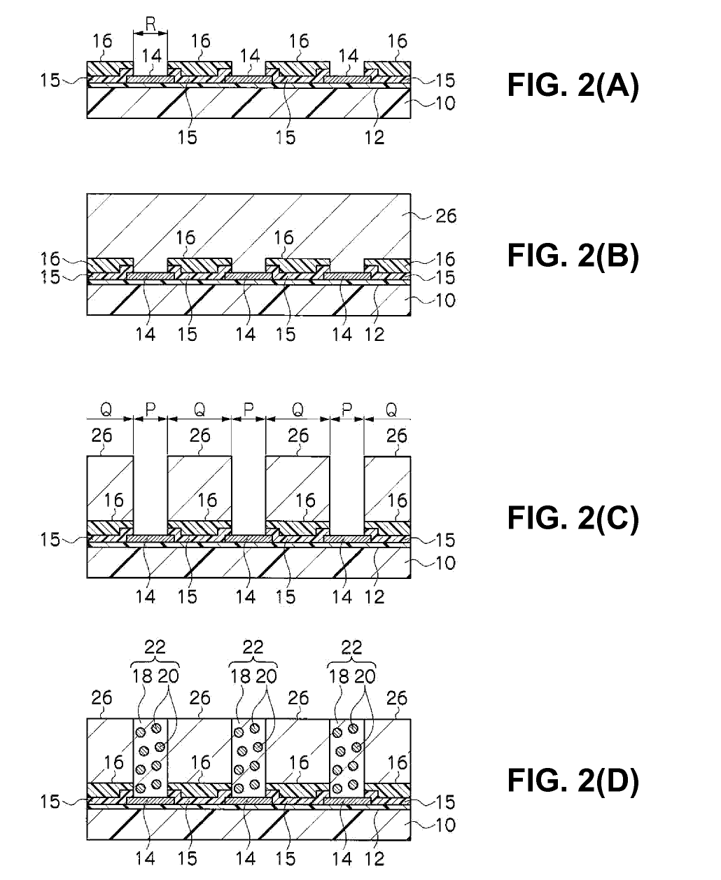

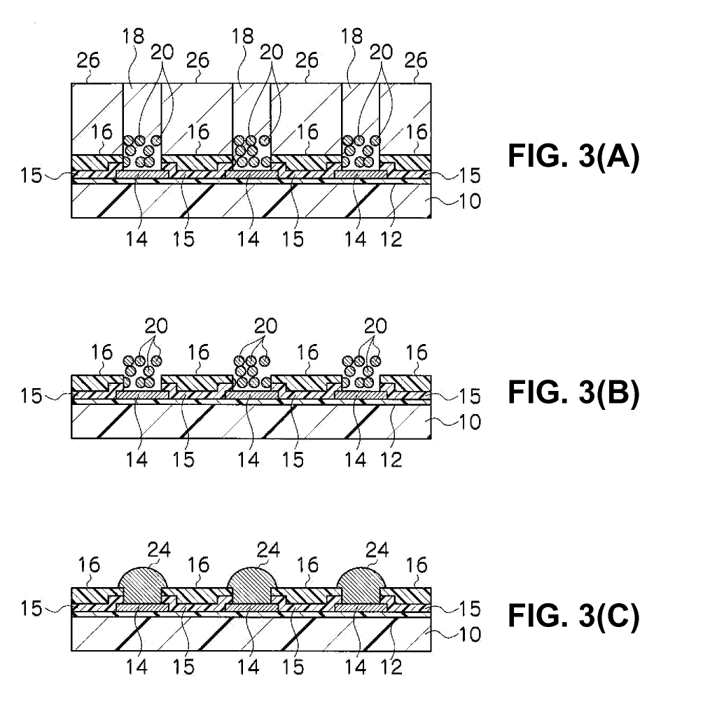

A second embodiment of the present invention will be explained next. FIGS. 2(A) to 2(D) are schematic sectional views No. 1 showing an electrical component in a manufacturing process using a method of producing the electrical component according to the second embodiment of the present invention. FIGS. 3(A) to 3(C) are schematic sectional views No. 2 showing the electrical component in the manufacturing process using the method of producing the electrical component according to the second embodiment of the present invention.

In the embodiment, a bump, a wiring portion, or an electrode is formed with the method of producing the electrical component according to the second embodiment of the present invention. In the following description, a process of forming the bump is explained as an example.

As shown in FIG. 2(A), a preparation process is performed. The preparation process in the second embodiment is similar to that in the first embodiment, and an explanation thereof is omitted.

In the next step, as shown in FIG. 2(B), a non-containing photosensitive resist coating process is performed. More specifically, a non-containing photosensitive resist 26 without the metal powders 20 is uniformly coated on the insulation film 16 and the exposed surfaces of the electrodes 14. Accordingly, it is possible to form a uniform layer of the non-containing photosensitive resist 26. It is noted that the non-containing photosensitive resist 26 is coated to have a thickness according to a height of the bump to be formed.

In the next step, as shown in FIG. 2(C), an exposure developing process is performed. More specifically, the non-containing photosensitive resist 26 coated on the insulation film 16 is removed within a range of a width P with the exposure developing device, so that the non-containing photosensitive resist 26 coated on the exposed surfaces of the electrodes 14 remains within a range of a width Q. As a result, holes or grooves reaching the exposed surfaces are formed. It is noted that the exposure developing device includes a well-known device, and detailed explanation is omitted.

In the next step, as shown in FIG. 2(D), a powder containing photosensitive resist coating process is performed. More specifically, after the non-containing photosensitive resist 26 is removed in the exposure developing process, the powder containing photosensitive resist 22 is filled in the holes or the grooves up to a level same as the non-containing photosensitive resist 26.

In the powder containing photosensitive resist coating process, it is possible to use the powder containing photosensitive resist 22 similar to that in the first embodiment. Accordingly, the layers of the powder containing photosensitive resist 22 are selectively formed on the electrodes 14. It is noted that the non-containing photosensitive resist 26 still partially remains coated on the insulation film 16.

In the next step, as shown in FIG. 3(A), a thermal process is performed. A specific procedure of the thermal process is similar to that in the first embodiment shown in FIG. 1(D), and an explanation thereof is omitted.

In the next step, as shown in FIG. 3(B), a photosensitive resist removal process is performed. In the photosensitive resist removal process, not only the photosensitive resist 18 contained in the powder containing photosensitive resist 22, but also the non-containing photosensitive resist 26 coated on the insulation film 16 is removed. A specific procedure of the photosensitive resist removal process is similar to that in the first embodiment shown in FIG. 1(E), and an explanation thereof is omitted.

In the next step, as shown in FIG. 3(C), the thermal process is performed one more time. A specific procedure of the thermal process is similar to that in the first embodiment shown in FIG. 1(F), and an explanation thereof is omitted.

As described above, in the second embodiment, the powder containing photosensitive resist 22 is coated on only the exposed surfaces of the electrodes 14. Accordingly, in addition to the effect in the first embodiment, it is possible to reduce consumption of the powder containing photosensitive resist 22.

In the above description, the method of producing the electrical component is adopted to form the bumps 24, and may be applied to form a wiring portion or an electrode with great flexibility through a similar process.

### Third Embodiment

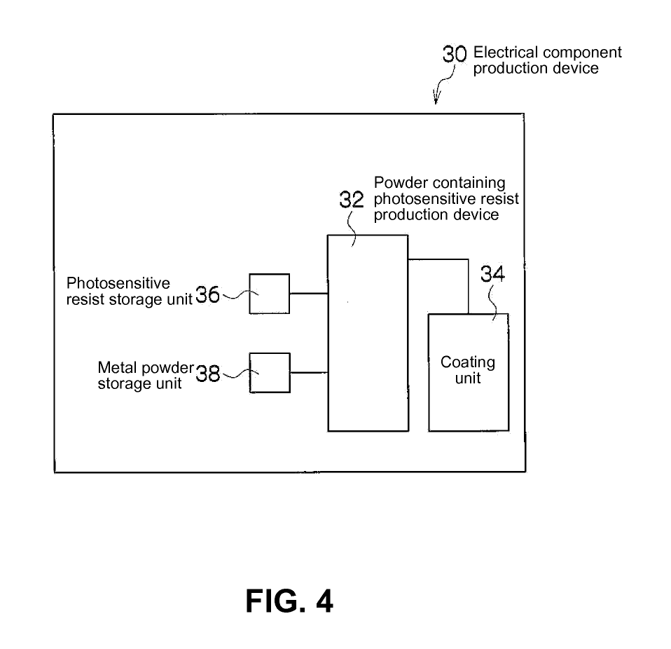

A third embodiment of the present invention will be explained next. FIG. 4 is a schematic view showing a configuration of an electrical component production device 30 according to the third embodiment of the present invention.

As shown in FIG. 4, the electrical component production device 30 includes a powder containing photosensitive resist production device 32. Further, the electrical component production device 30 includes a photosensitive resist storage unit 36 for retaining a photosensitive resist; a metal powder storage unit 38 for retaining metal powders; and a coating unit 34 for coating a powder containing photosensitive resist.

In the embodiment, the powder containing photosensitive resist production device 32 mixes the photosensitive supplied from the resist the photosensitive resist storage unit 36 and the metal powders supplied from the metal powder storage unit 38 to produce a powder containing photosensitive resist. Then, the powder containing photosensitive resist production device 32 supplies the powder containing photosensitive resist to the coating unit 34.

In the embodiment, with the configuration described above, it is possible to uniformly disperse the metal powders or conductive powders in the photosensitive resist before supplying the powder containing photosensitive resist to the coating unit 34. Accordingly, it is possible to uniformly coat the powder containing photosensitive resist with the coating unit 34, thereby making it possible to form a bump, a wiring portion or an electrode with great flexibility.

The disclosure of Japanese Patent Application No. 2010-035317, filed on Feb. 19, 2010, is incorporated in the application by reference.

While the invention has been explained with reference to the specific embodiments of the invention, the explanation is illustrative and the invention is limited only by the appended claims.

What is claimed is:

1. A method of producing an electrical component comprising the steps of:
selectively forming a powder containing organic layer containing conductive powders on an exposed surface of a first conductive member exposed through an opening portion formed in an insulation film; and
thermally processing the powder containing organic layer to agglutinate the conductive powders so that a second conductive member electrically connected to the first conductive member is formed on the exposed surface.

2. The method of producing the electrical component according to claim 1, wherein, in the step of selectively forming the powder containing organic layer containing the conductive powders on the exposed surface of the first conductive member exposed through the opening portion formed in the insulation film, said powder containing organic layer is formed of a photosensitive resist containing the conductive powders.

3. The method of producing the electrical component according to claim 2, in the step of selectively forming the powder containing organic layer on the exposed surface of the first conductive member, further comprising the steps of uniformly coating the photosensitive resist containing the conductive powders on the insulation film and the exposed surface, and removing the photosensitive resist coated on the insulation film with an exposure developing device.

4. The method of producing the electrical component according to claim 2, in the step of selectively forming the powder containing organic layer on the exposed surface of the first conductive member, further comprising the steps of uniformly coating a photosensitive resist without the conductive powders on the insulation film and the exposed surface; removing the photosensitive resist coated on the exposed surface with an exposure developing device so that a hole or a groove reaching the exposed surface is formed; and filling the hole or the groove with the photosensitive resist containing the conductive powders.

5. The method of producing the electrical component according to claim 1, wherein, in the step of thermally processing the powder containing organic layer to agglutinate the conductive powders so that the second conductive member electrically connected to the first conductive member is formed on the exposed surface, said second conductive member is formed to have a height adjusted through adjusting a thickness of the powder containing organic layer coated on the exposed surface, or an amount of the conductive powders contained in the powder containing organic layer.

6. The method of producing the electrical component according to claim 1, wherein, in the step of thermally processing the powder containing organic layer to agglutinate the conductive powders so that the second conductive member electrically connected to the first conductive member is formed on the exposed surface, said second conductive member is formed of at least one of a bump, a wiring portion, or an electrode.

7. The method of producing the electrical component according to claim 1, wherein, in the step of selectively forming the powder containing organic layer on the exposed surface of the first conductive member, said conductive powders are formed of solder powders.

8. An electrical component production device comprising:
a powder containing organic solution production device for mixing conductive powders in an organic solvent to produce a powder containing organic solution.

9. A photosensitive resist comprising:
conductive powders capable of being agglutinated through a thermal process.
